(19) United States
(12) Patent Application Publication
(10) Pub. No.: US 2002/0113600 A1
(43) Pub. Date: Aug. 22, 2002

(54) VSWR monitor and alarm

(76) Inventor: John D. Swank II, Hudson, OH (US)

Correspondence Address: RANKIN, HILL, PORTER & CLARK, LLP, 700 HUNTINGTON BUILDING, 925 EUCLID AVENUE, CLEVELAND, OH, 44115-1405, US

(21) Appl. No.: 09/750,478

(22) Filed: Dec. 28, 2000

(51) Int. Cl. G01R 27/04; G01R 27/32

(52) U.S. Cl. 324/637

(57) ABSTRACT

A VSWR meter and alarm device that produces an alarm when an undesirable VSWR is sensed on an RF transmission line. This device uses a single-arm directional coupler and detectors operating at least 15 dB into the “square law region” at full power. The single-arm directional coupler is capable of sensing the forward voltage wave and reflected voltage wave from a transmission line. The coupler isolates the forward and reflected voltages and each is converted into a direct current (dc) signal by a full-wave detector. Attenuator circuits are utilized between the coupler and detectors so that the detectors operate at least 15 dB into the “square-law region” at full power. The dc signals representing the forward and reflected voltages are then amplified and transformed into respective digital signals by a digital-to-analog converter. The digital signals are then transmitted to a microprocessor which operates an alarm system.

This invention relates to an electrical instrument for monitoring RF transmitters to measure both forward and reflected power or an RF transmission line and especially to activate an alarm when an undesirable VSWR is detected. The instrument has particular utility in connection with cellular telecommunication systems.

The instrument is adapted to be inserted in an RF transmission line and continuously monitors the forward and reflected voltage waves using a directional coupler that may be specifically designed for the cellular band. From the voltage measurements, the VSWR is calculated and compared to a selectable maximum ratio. An alarm is activated when the VSWR exceeds the selected maximum ratio.

In RF transmission systems, power reflected from the transmitting antenna reduces the efficiency of the broadcast, and subsequently reduces broadcast coverage. It is desirable, therefore, to be able to monitor this reflected power and activate an alarm if it exceeds a preset value. Reflected power is usually expressed indirectly as voltage standing wave ratio or VSWR. Mathematically, VSWR is related to forward and reflected power by:

$$VSWR = \frac{1 + \sqrt{\frac{{Power}_{reverse}}{{Power}_{forward}}}}{1 - \sqrt{\frac{{Power}_{reverse}}{{Power}_{forward}}}}$$

Traditionally, this measurement is made using directional resistive bridges, dual-directional couplers, or reactance bridges in combination with diode detectors. These techniques have certain limitations however.

First of all, separate forward and reverse couplers require precise internal reference terminations and can introduce computational errors due to mismatch in coupling and directivity. Bridges depend on component matching for accuracy.

Diode detectors operating in the linear detection region are not accurate when used with digital or multi-carrier modulation systems where high peak-to-average power ratios are common.

In view of these limitations, a need exists for a monitor/alarm that utilizes a directional coupler with intrinsically high directivity, that may be used in conjunction with wide dynamic-range average responding detectors.

The instrument of the present invention satisfies the needs described above and affords other features and advantages heretofore not obtainable.

### SUMMARY OF THE INVENTION

It is among the objects of the present invention to provide an electrical instrument for monitoring RF transmitters so as to activate an alarm when an excessive VSWR is detected.

Another object is to provide such an instrument that may be placed in an antenna feed circuit to monitor the forward and reflected voltage waves using a directional coupler specifically designed for the cellular band.

Still another object is to provide an instrument of the type described that may be used in either analog or digital cellular telecommunication systems.

These and other objects and advantages are achieved with the novel device of the present invention.

The invention provides a VSWR monitor and alarm that generates an alarm when an excessive VSWR is detected on an RF transmission line. The device uses a single-arm directional coupler that senses the forward voltage wave and reflected voltage wave on the transmission line. The coupler isolates the forward and reflected voltages and each is converted into a DC signal by a full wave detector. The respective DC signals are amplified and converted into digital signals by a digital to analog converter. The digital signals are then transmitted to a microprocessor that calculates the VSWR, compares it to a preselected maximum ratio and then operates an alarm system if an excessive VSWR is detected.

### BRIEF DESCRIPTION OF THE DRAWINGS

FIG. 1 is a front elevation of a VSWR monitor/alarm embodying the invention;

FIG. 2 is a top plan view of the device of FIG. 1; and

FIG. 3 is a block diagram illustrating the arrangement of the electrical components used in the device of FIGS. 1 and 2.

### DETAILED DESCRIPTION OF THE INVENTION

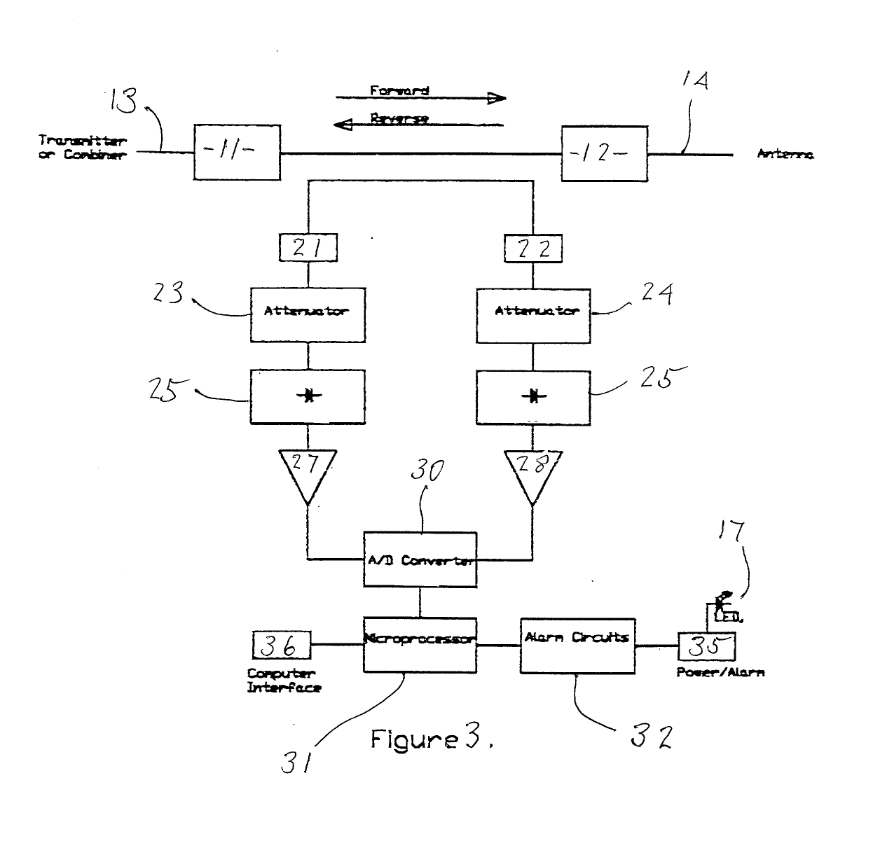

Referring more particularly to the drawings, there is shown a VSWR monitor and alarm device 10 particularly adapted for use in a cellular telecommunication system and embodying one form of the invention. The device has a rectangular housing containing the electronic components of the instrument. These components are described with reference to FIG. 3.

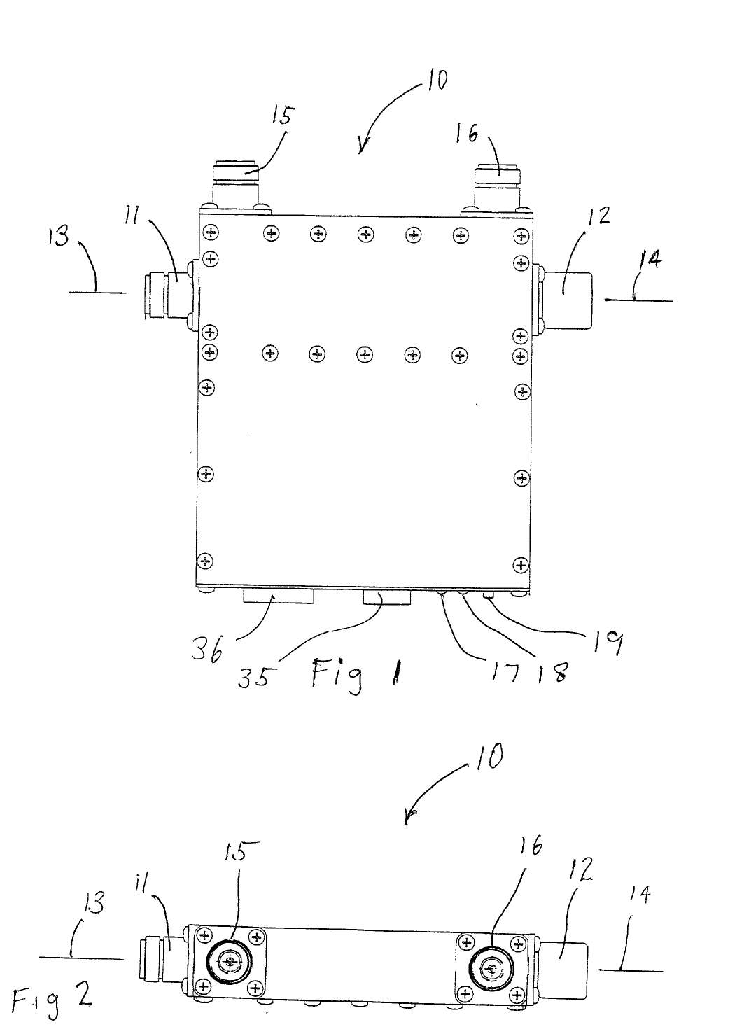

Referring to FIGS. 1 and 2, an RF input connector 11 is mounted on one side of the housing and an RF output connector 12 is mounted on the opposite side. The connector 11 is an “N” type female connector adapted to be connected to the cable 13 from the amplifier. The connector 12 is an “N” type male connector adapted to be connected to the cable 14 leading to the antenna.

A forward power monitor port 15 and a reflected power monitor port 16 are located at the top of the housing as shown in FIGS. 1 and 2. The ports 15 and 16 are type “N” male connectors.

An alarm LED 17, an operation/test LED 18 and a reset switch 19 are mounted at the bottom of the housing as shown in FIG. 1. 17 is a red LED, 18 is a green LED and the switch 19 resets the device as required.

Also mounted at the bottom of the housing are an RS-232 type serial port 35 for use in connecting the device to a PC, and a power/alarm parallel port 36 for use in adapting the device for remote operation and for supplying power to the unit.

The theory of operation of the type of directional coupler used in connection with the invention is well known and will not be described in detail. However, the theory of operation is thoroughly described in U.S. Pat. No. 4,547,728 which is incorporated by reference herein.

Referring to FIG. 3, it will be seen that the forward voltage on the transmission line is sensed by the directional coupler 21 and the resulting voltage signal is transmitted to an attenuator 23 and then to a diode detector 25. The dc signal from the diode detector 25 is amplified by an amplifier 27.

The reflected voltage on the transmission line is sensed by the directional coupler 22 and the resulting voltage signal is transmitted to an attenuator 24 and then to a diode detector 26. The dc signal from the detector 26 is amplified by the amplifier 28.

The dc signals from the amplifiers 27 and 28 are supplied to an analog to digital converter 30 and the resulting digital signals are supplied to a microprocessor 31. The microprocessor 31 processes the two signals and determines the VSWR, which is then compared to a preselected maximum ration. If an excessive VSWR occurs, a signal is sent to the alarm circuits 32, which can generate an alarm signal to activate the LED 17 or to be outputted to a remote device through the power/alarm port 36.

The signal at the forward power directional coupler 21 is isolated from the diode detector 25 by the attenuator 23. The characteristics of this attenuator are critical to the proper operation of the alarm system. More specifically, attenuation value must be such that the diode detector 25 operates at at least 15 dB into the “square-law region” at full scale power. Also, the impedance match of the attenuator 23 to the impedance of the coupled line must be of high quality. Typically, the attenuation is set to 30 dB and the impedance match produces reflections representing less than 1% of the incident power.

Likewise, the signal at the reflected power directional coupler 22 is isolated from the diode detector 26 by the attenuator 24. As with the attenuator 25, the characteristics of the attenuator 26 are critical to the proper operation of the device. Here again the attenuation value must be such that diode detector 10 operates at least 15 dB into the “square-law region” at full scale power. As with the attenuator 23, the impedance match of the attenuator 24 to the coupled line must also be of high quality.

These are the characteristics that permit forward and reflected power information to be extracted from a single coupled arm. Previously, a dual directional coupler was needed to achieve this level of performance. The attenuation value chosen is based on the required full scale power desired and can be adjusted as necessary for other full scale power indications.

The detectors 25 and 26 are full wave detectors. This configuration improves average power detection for RF signals with asymmetric modulation characteristics such as those found in digital modulation systems. Although this detector configuration has been used in voltage measuring instruments for many years, the present device restricts the maximum average input signals such that peak envelope excursions of 15 dB are still within the “square-law region”.

The amplifiers 27 and 28 increase the level of the respective dc signals from the detectors 25 and 26 respectively to an appropriate level for conversion by the analog to digital converter 30.

The digital representations of the forward and reflected voltages from the converter 30 are processed by the microprocessor 31. If the VSWR is not within the previously determined limits, an alarm is generated by the alarm circuit 32. The output from the alarm circuit 32 is available for external connection through the power/alarm connector 42. One indicator is a set of isolated relay contacts (open and close); another is a TTL logic level signal; and a third is a local visual indicator in the form of the red LED 17.

Operating power is supplied to the device through the power/alarm connector 42. Circuitry is provided to allow DC input voltage variations over limits normally expected in transmitter sites.

VSWR alarm points are set in the microprocessor 31 by means of the computer interface connector 35. Also, data may be transferred into an external computer and displayed through the same interface 35.

In a typical embodiment of the invention the voltage standing wave ratio is calculated and compared to a selectable maximum ratio of 1.3, 1.4, 1.5, 1.6, 1.7 or 1.8 to 1. Based on the results of the comparison, possible actions include:

1. No alarms are activated if the result of the calculation is less than the maximum setting.

2. For a result greater than the maximum setting but less than the maximum plus 0.1 VSWR, readings are accumulated for about 30 seconds. If the average of all the readings exceeds the maximum setting, an alarm is activated. For a result greater than the maximum plus 0.1 but less than the maximum plus 0.2 VSWR, readings are accumulated for about 10 seconds. If the average of all the readings exceeds the maximum setting, an alarm is activated.

3. For a result much greater than the maximum setting, the alarm condition is activated immediately.

Typically forward and reflected average power measurements may cover a range of from 25 to 500 watts. Also, it will be apparent that the device may be used at any point in the RF transmission line between the transmitter and the antenna.

While the invention has been shown and described with respect to a specific embodiment thereof, this is intended for the purpose of illustration rather than limitation, and other modifications and variations in the specific form herein shown and described will be apparent to those skilled in the art, all within the intended spirit and scope of the invention. Accordingly, the patent is not to be limited in scope and effect to the specific embodiment herein shown and described nor in any other way that is inconsistent with the extent to which the progress in the art has been advanced by the invention.

1) an instrument for measuring the forward and reflected voltages on an RF transmission line and for activating an alarm when an excessive VSWR is detected, comprising;
directional coupler means for measuring the forward voltage wave and reflected voltage wave on an RF transmission line and for generating voltage signals representative thereof, the respective signals being isolated from one another;
means for processing each of said signals to generate respective dc voltage signals;
means for amplifying each of said dc voltage signals;
means for converting each of said amplified signals to a digital signal; and
a microprocessor for determining the VSWR from said digital signals and for comparing said VSWR to a selected maximum ratio so as to activate an alarm when said selected maximum ratio is exceeded:

2) A process for measuring the forward and reflected voltages on an RF transmission line and for activating an alarm when an excessive VSWR is detected comprising the steps of;
sensing the forward voltage level on said RF transmission line using a first directional coupler and generating a first voltage signal representative thereof;
simultaneously sensing the reflected voltage level on said RF transmission line using a second directional coupler isolated from said first directional coupler and generating a second voltage signal representative thereof and isolated from said first signal;
attenuating each of said signals;
amplifying each of said attenuated signals;
converting each of said amplified signals to a digital signal;
determining the VSWR on said RF transmission line by processing said amplified signals, and;
comparing said VSWR to a preselected maximum ratio to detect a VSWR that exceeds the preselected maximum, and;
generating an alarm when said excessive VSWR is detected.
